(19) United States
(12) Patent Application Publication
(10) Pub. No.: US 2020/0371570 A1
(43) Pub. Date: Nov. 26, 2020

(54) DISPLAY SCREEN AND ELECTRONIC DEVICE

(71) Applicant: Wuhan China Star Optoelectronics Semiconductor Display Technology Co. Ltd., Wuhan (CN)

(72) Inventors: Yijia WANG, Wuhan (CN); Rui LU, Wuhan (CN)

(21) Appl. No.: 16/611,478

(22) PCT Filed: Sep. 27, 2019
(86) PCT No.: PCT/CN2019/108484

§ 371 Date: Nov. 7, 2019

(30) Foreign Application Priority Data
May 23, 2019 (CN) 201910432164.4

(51) Int. Cl. G06F 1/20; G06F 1/16; H01L 51/00; H01L 51/52; G02F 1/1333

(52) U.S. Cl. CPC G06F 1/203; G06F 1/1652; G02F 1/133382; H01L 51/529; H01L 51/0097

(57) ABSTRACT

A display screen and an electronic device are provided, and the display screen comprises a display panel; a heat dissipation film is disposed on the back surface of the display panel. The heat dissipation film comprises a heat conduction layer, and the heat conduction layer comprises at least one selected from the group consisting of a carbon nanowall, a metal nanowall, an oxide nanowall, and a combination thereof. The display screen and the electronic device of the present disclosure can improve the effect of heat dissipation.

### FIELD OF INVENTION

The present disclosure relates to the field of display technologies, and more particularly to a display screen and an electronic device.

### BACKGROUND OF INVENTION

Flexible organic light-emitting diode (OLED) display screens have low power consumption, high resolution, fast response, and bendability properties, and become a popular development direction in display industry. The thinner the thickness of a display screen, means greater market competitiveness.

Currently, a thin film transistor (TFT), an OLED, and a thin film encapsulation (TFE) are disposed on a flexible substrate in sequence, and in order to drive the thin film transistor, it is necessary to bond a drive circuit at a bottom of the flexible substrate to form a display screen.

However, when the display screen is working, current passes through the TFT circuit, and heat is generated. In order to facilitate heat dissipation, a heat dissipation film is usually disposed on a back surface of the display screen. However, the heat conduction direction of current heat dissipation films is horizontal and parallel to the display panel. Since heat is mainly conducted in the horizontal direction, the heat dissipation of the display screen is poor.

Therefore, it is necessary to provide a display screen and an electronic device to solve the existing problems in the prior art.

### SUMMARY OF INVENTION

The present disclosure provides a display screen and an electrical device for improving heat dissipation.

To solve above technical problems, the present disclosure provides a display screen. The display screen comprises:

a display panel; and

a heat dissipation film disposed on a back surface of the display panel. The heat dissipation film comprises: a heat conduction layer, comprising at least one selected from the group consisting of a carbon nanowall, a metal nanowall, an oxide nanowall, and a combination thereof.

The present disclosure provides an electronic device, which comprises the display screen.

The display screen and the electronic device provided by the present disclosure comprise a heat dissipation film disposed on the back surface of the display panel, and the heat dissipation film comprises a heat conduction layer. The heat conduction layer comprises at least one selected from the group consisting of a carbon nanowall, a metal nanowall, an oxide nanowall, and a combination thereof. By using at least one selected from the group consisting of a carbon nanowall, a metal nanowall, an oxide nanowall, and a combination thereof to prepare the heat conduction layer makes the heat conduction direction of the heat conduction layer perpendicular to the display panel, thereby making the heat dissipation channel larger and shortening the heat dissipation path to facilitate heat dissipation.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a schematic structural diagram of a current display screen.

FIG. 2 is a schematic structural diagram of a display screen according to embodiment 1 of the present disclosure.

FIG. 3 is a schematic structural diagram of a display panel of the present disclosure.

FIG. 4 is a preferred schematic structural diagram of a display screen according to embodiment 1 of the present disclosure.

FIG. 5 is a first top view of a heat conduction layer of the present disclosure.

FIG. 6 is a second top view of a heat conduction layer of the present disclosure.

FIG. 7 is a third top view of a heat conduction layer of the present disclosure.

FIG. 8 is a fourth top view of a heat conduction layer of the present disclosure.

FIG. 9 is a top view of a nanowall of the present disclosure.

FIG. 10 is a schematic structural diagram of a display screen according to example 2 of the present disclosure.

FIG. 11 is a schematic structural diagram of a display screen according to example 3 of the present disclosure.

### DETAILED DESCRIPTION OF PREFERRED EMBODIMENTS

Following examples of the described embodiments are given in the accompanying drawings, and the specific embodiments described with reference to the attached drawings are all exemplary and are intended to illustrate and interpret the present disclosure. In the description of the present disclosure, it should be understood that terms such as “top,” “bottom,” “front,” “rear,” “left,” “right,” “inside,” “outside,” “side” as well as derivative thereof should be construed to refer to the orientation as then described or as shown in the drawings under discussion. These relative terms are for convenience of description, do not require that the present disclosure be constructed or operated in an orientation, and shall not be construed as causing limitations to the present disclosure. In the figures, elements with similar structures are denoted by the same reference numerals.

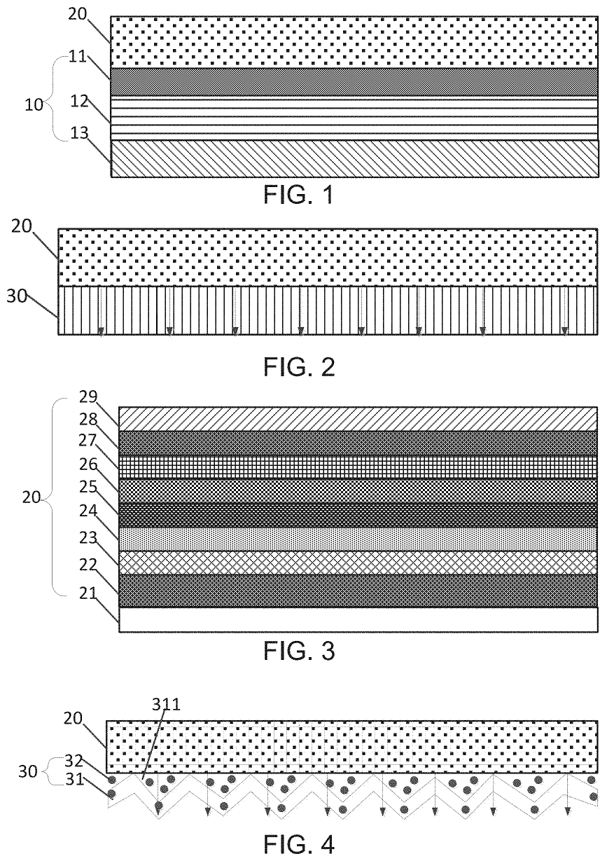

As shown in FIG. 1, the current display screen comprises a heat dissipation film 10 and a display panel 20, and the heat dissipation film 10 usually contains a three-in-one structure of foam 11, graphite 12, and copper foil 13; however, graphite 12 is a sheet structure, and heat is mainly conducted along the length of the graphite layer; that is, the heat conduction direction of the current heat dissipation film is horizontal (as shown by the direction of the arrow in FIG. 1). The heat dissipation film 10 is a three-layer structure, which is thicker.

Please refer to FIG. 2 to FIG. 4, FIG. 2 is a schematic structural diagram of the display screen according to embodiment 1 of the present disclosure.

As shown in FIG. 2, the display screen of the example comprises a display panel 20 and a heat dissipation film 30.

Combined with FIG. 3, the display panel 20 can be a liquid crystal display panel or an organic light-emitting diode display panel. When the display panel 20 is an organic light-emitting diode display panel, in one embodiment, the display panel 20 comprises a backboard 21, a flexible substrate 22, a switch array layer 23, an organic light-emitting display layer 24, a thin film encapsulation 25, an optical adhesive 26, a touch layer 27, a polarizer 28, and a cover sheet 29. The switch array layer 23 is disposed on the flexible substrate 22; the switch array layer 23 comprises a plurality of thin film transistors, and its cross-sectional structure includes a cushioning layer, a semiconductor layer, a gate insulating layer, a gate electrode, a first insulating layer, a metal portion, a second insulating layer, a second metal layer, and a third insulating layer. The second metal layer includes a source electrode and a drain electrode.

The organic light-emitting display layer 24 comprises an anode, an organic light-emitting layer, and a cathode. The material of the anode can be a metal material. The anode is connected to the drain of thin film transistors. The organic light emitting layer includes a red light emitting layer, a green light emitting layer, a blue light emitting layer, and the like from a top view angle. The cathode is disposed on the organic light emitting layer.

The heat dissipation film 30 is disposed on the back surface of the display panel 20, for example disposed under the display panel 20. The heat dissipation film 30 can be attached to the back surface of the backboard 21. The heat conduction direction of the heat dissipation film 30 (as shown by the direction of the arrow in FIG. 2) is perpendicular to the surface of the display panel 20. For example, the surface is perpendicular to the thickness direction of the display panel, and in one embodiment, the surface is parallel to the horizontal plane.

In an embodiment of the present disclosure, as shown in FIG. 4, the heat dissipation film 30 comprises a heat conduction layer 31, and in one embodiment, the heat conduction layer 31 comprises at least one selected from the group consisting of a carbon nanowall, a metal nanowall, an oxide nanowall, and a combination thereof. To further improve the effect of heat dissipation, the heat conduction direction of the heat conduction layer 31 (as shown by the direction of the arrow in FIG. 2) is perpendicular to the surface of the display panel 20. For example, heat conduction direction of the heat conduction layer 31 is vertical.

Wherein the structure of the heat conduction layer 31 is a two-dimensional structure perpendicular to the surface of the display panel 20. The manufacturing method of the heat conduction layer 31 comprises but not limited to PECVD, ALD, PLD and so on. The heat conduction layer 31 can also be prepared by a deposition process.

In an embodiment of the present disclosure, wherein the heat conduction layer 31 includes a gap 311, the gap 311 is filled with a cushioning material 32 to increase the service life of the display screen and prevent damages to the display panel during bending. Wherein the cushioning material 32 comprises an elastic polymer. And materials of the heat conduction layer 31 can also be doped with the cushioning material 32. The cushioning material 32 has good elasticity and flexibility to buffer the stress on the heat conduction layer and to prevent damages to the display screen. The thickness of the cushioning layer is reduced at the same time, thereby reducing the overall thickness of the display screen.

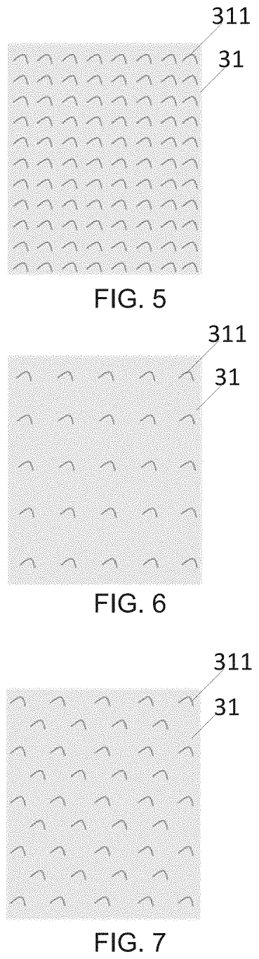

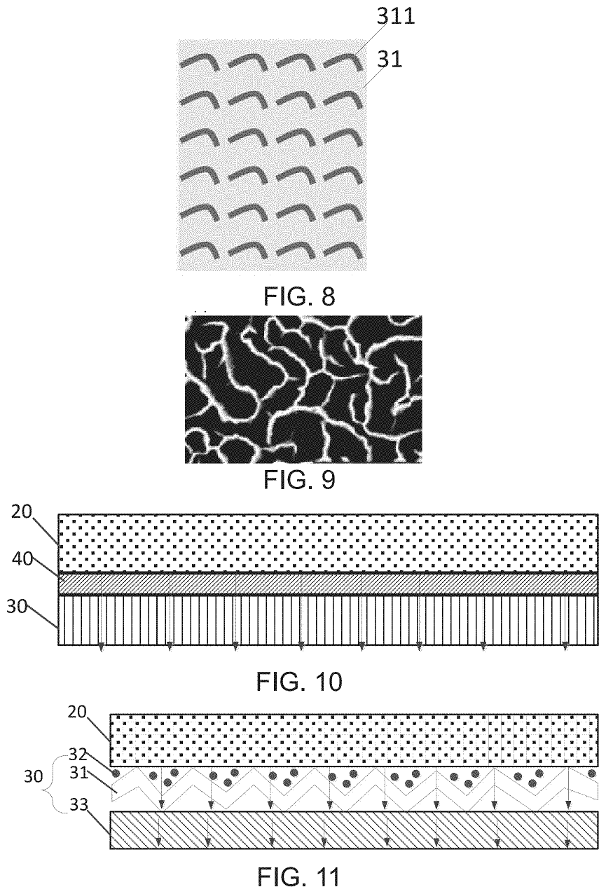

As shown in FIG. 5 to FIG. 8, from a top view angle, the surface of the heat conduction layer 31 is wavy, wherein the intervals between the two-dimensional vertical heat conduction structures 311 of the heat conduction layer 31 can be arranged according to requirements, and different intervals between the vertical heat conduction structures 311 are given in FIG. 5 to FIG. 7. Wherein the thickness of the vertical heat conduction structures 311 in FIG. 8 is different from the thickness in FIG. 5 to FIG. 7. The thickness of the vertical heat conduction structures 311 can be arranged according to requirements. It should be understood, the surface of the heat conduction layer 31 can be planar. FIG. 9 is a top view of a nanowall with a thickness of 0.5 micrometers.

Because using at least one selected from the group consisting of a carbon nanowall, a metal nanowall, an oxide nanowall, and a combination thereof to prepare the heat conduction layer makes the heat conduction direction of the heat dissipation film perpendicular to the surface of the display panel, thereby making the heat dissipation channel larger and shortening the heat dissipation path to improve the effect and efficiency of heat dissipation. In addition, because it is not necessary for the heat dissipation film to set a foam layer, the thickness of the display screen is reduced.

To further reduce the thickness of the display screen, the thickness of the heat dissipation film 30 ranges from 50 μm to 150 μm. It should be understood, when the heat dissipation film 30 is a multilayer structure, the thickness of the heat dissipation film 30 is the sum of the thickness of each layer.

Referring to FIG. 10, FIG. 10 is a schematic structural diagram of the display screen according to example 2 of the present disclosure.

As shown in FIG. 10, the display screen further comprises a cushioning layer 40, the cushioning layer 40 is disposed between the heat dissipation film 30 and the display panel 20, and more specifically, disposed between the heat dissipation film 30 and the back surface of the display panel 20. The material of the cushioning layer 40 is a cushioning material.

Because the cushioning material has good elasticity and flexibility, it can buffer the stress on the heat conduction layer and prevent damages to the display screen.

Referring to FIG. 11, FIG. 11 is a schematic structural diagram of the display screen according to example 3 of the present disclosure.

As shown in FIG. 11, based on embodiment 1, the heat dissipation film 30 further comprises a metal layer 33, the metal layer 33 is disposed on one side of the heat conduction layer 31 away from the display panel 20. That is, the metal layer 33 is disposed under the heat conduction layer 31. Wherein the material of the metal layer 33 is copper foil.

Specifically, the heat conduction layer 31 can be directly deposited on the copper foil, then filled with cushioning materials to obtain the heat dissipation film, and attach the heat dissipation film 30 on the back surface of the display panel after that.

Based on embodiment 1, due to disposing a metal layer under the heat conduction layer 31, thereby improving the effect of heat dissipation to better dissipate heat of the display screen.

The present disclosure further provides an electronic device, comprising any of the above display screen.

The display screen and the electronic device provided by the present disclosure comprise a heat dissipation film disposed on the back surface of the display panel, and the heat dissipation film comprises a heat conduction layer; the heat conduction layer comprises at least one selected from the group consisting of a carbon nanowall, a metal nanowall, an oxide nanowall, and a combination thereof. By using at least one selected from the group consisting of a carbon nanowall, a metal nanowall, an oxide nanowall, and a combination thereof to prepare the heat conduction layer makes the heat conduction direction of the heat conduction layer perpendicular to the display panel, thereby making the heat dissipation channel larger and shortening the heat dissipation path to facilitate heat dissipation.

In the description of the present disclosure, the description with reference to the terms “one embodiment”, “some embodiments”, “illustrative embodiment”, “example”, “specific example”, or “some examples”, etc. means to combine specific features, structures, or materials in the embodiment or example, or features included in at least one embodiment or example of the invention. In the present disclosure, the schematic representation of the above terms does not necessarily mean the same embodiment or example. Moreover, the specific features, structures, materials, or characteristics described may be combined in any suitable manner in any one or more embodiments or examples.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A display screen, comprising: a display panel; and a heat dissipation film disposed on a back surface of the display panel; the heat dissipation film comprising:
a heat conduction layer comprising at least one selected from the group consisting of a carbon nanowall, a metal nanowall, an oxide nanowall, and a combination thereof, and the heat conduction layer including a gap; wherein the gap is filled with a cushioning material;
wherein materials of the heat conduction layer are doped with the cushioning material, and the cushioning material comprises an elastic polymer.

2. A display screen, comprising:
a display panel; and a heat dissipation film disposed on a back surface of the display panel; the heat dissipation film comprising:
a heat conduction layer, comprising at least one selected from the group consisting of a carbon nanowall, a metal nanowall, an oxide nanowall, and a combination thereof.

3. The display screen according to claim 2, the heat conduction layer including a gap; wherein the gap is filled with a cushioning material.

4. The display screen according to claim 2, materials of the heat conduction layer are doped with a cushioning material.

5. The display screen according to claim 4, the cushioning material comprises an elastic polymer.

6. The display screen according to claim 2, a thickness of the heat dissipation film ranges from 50 μm to 150 μm.

7. The display screen according to claim 2, a heat conduction direction of the heat conduction layer is perpendicular to a display surface of the display panel.

8. The display screen according to claim 2, the heat dissipation film further comprising:
a metal layer disposed on one side of the heat conduction layer away from the display panel.

9. The display screen according to claim 2, the display screen further comprising a cushioning layer, the cushioning layer is disposed between the heat dissipation film and the display panel.

10. The display screen according to claim 2, the display panel is an organic light-emitting diode display panel or a liquid crystal display panel.

11. An electronic device, comprising the display screen according to claim 1.
